(19) United States
(12) Patent Application Publication
(10) Pub. No.: US 2014/0357066 A1
(43) Pub. Date: Dec. 4, 2014

(54) METHODS OF CRYSTALLISING THIN FILMS

(71) Applicant: Roger Dunstan Jeffery, Brisbane (AU)

(72) Inventor: Roger Dunstan Jeffery, Brisbane (AU)

(73) Assignee: Panorama Synergy, Ltd., Brisbane (AU)

(21) Appl. No.: 14/343,810

(22) PCT Filed: Sep. 6, 2012
(86) PCT No.: PCT/AU2012/001053

§ 371 Date: Jul. 8, 2014

(30) Foreign Application Priority Data
Sep. 9, 2011 (AU) AU 2011903679

(51) Int. Cl. H01L 21/02

(52) U.S. Cl. CPC H01L 21/02689; H01L 21/02565; H01L 21/0254; H01L 21/02631
USPC 438/487

(57) ABSTRACT

A method of crystallising a thin film (220) including the steps of: depositing a thin film (220) on a substrate (210; and exposing the thin film (220) as deposited on the substrate (210) and the substrate (210) to a plasma for a time period of greater than 5 minutes, wherein: the thin film (220) is one of an amorphous magneto optic material, an amorphous electro optic material or a nitride material; a gas (130) is excited with a radio frequency (RF) field to form the plasma; the thin film (220) and the substrate (210) are, in the course of being exposed to the plasma, heated to temperatures of between 400° C. and 550° C. by the plasma; and the thin film (220) is at least partially crystallised by the plasma.

### FIELD OF THE INVENTION

This invention relates generally to a method of crystallising thin films. In particular the invention relates to crystallising thin films on a same substrate as an integrated circuit.

### BACKGROUND OF THE INVENTION

In order to crystallise thin films of an amorphous magneto optic material, such as rare earth doped bismuth iron garnets to produce an active magneto optic film, the amorphous magneto optic material is deposited on a substrate and annealed at high temperatures. Typically Rapid Thermal Annealing (RTA) is used in the temperature range 580 degrees Celsius (° C.) to 1000° C. in order to minimize the thermal budget. Similar temperatures are also required in order to anneal an amorphous electro optic material, to produce an active electro optic film.

The amorphous magneto optic material, or amorphous electro optic material, may be deposited using many different techniques such as Pulsed Laser Deposition (PLD), Radio Frequency (RF) Magnetron

Sputtering, and Ion Beam Deposition. Unless the substrate is heated to temperatures generally exceeding 550° C. and a latticed matched substrate is used, all of the above techniques result in substantially amorphous magneto optic and electro optic films which do not exhibit magneto-optic or electro-optic properties. The rare earth doped bismuth iron garnets may also be deposited epitaxially, from a melt, onto a latticed matched substrate, but this technique requires even higher thermal budgets and does not lend itself to forming tuned optical structures.

In order to facilitate direct deposition and crystallising of magnetically active rare earth doped bismuth iron garnets onto silicon integrated circuits the temperature should be kept below 540° C. and more optimally, less than 450° C., otherwise the integrated circuit may suffer damage. Consequently it has hitherto not been possible to produce active magneto optic or active electro optic films on the same substrate as the integrated circuit. Thus it has been necessary to form the active magneto optic or active electro optic film on a different substrate, and to interface the active magneto optic or active electric optic film with the integrated circuit using ion implantation and lift-off techniques and subsequent bonding to the integrated circuit. However bonding magnetic optic or electro optic devices to the integrated circuit is undesirable particularly if there are many magneto optic or electro optic elements. Furthermore, bonding the active magneto optic or active electro optic film with the integrated circuit results in a less reliable structure.

Similarly nitrides can be deposited using several different techniques commonly known to those working in the area. Gallium Nitride (GaN) is an important material in the area of UV detection, blue light generation and bio-compatible sensors. For optimal performance, the GaN must be well crystallized. Oven or RTA annealing of GaN normally requires temperatures between 900° C. and 1000° C. Accordingly, annealing GaN on a silicon integrated circuit and maintaining the function of the integrated circuit has not been feasible. In addition, Silicon Nitride is an important material used for passivation, waveguides and also for

Micro Electro Mechanical Systems (MEMS) cantilevers, and thermal annealing temperatures are generally in the range of 950° C. to 1200° C.

U.S. Pat. No. 7,132,373 discloses a method of crystallising oxide materials, such as TiO₂ and ITO using a plasma, at temperatures less than 180° C. However, the oxides disclosed in U.S. Pat. No. 7,132,373 are simpler oxides and the temperature claimed is not suitable for crystallising more complex oxides such as garnets and nitride films.

U.S. Pat. No. 6,432,725 discloses the crystallization of very thin oxides using a plasma at temperatures of less than 400° C. for a time period of less than 30 seconds. However U.S. Pat. No. 6,432,725 is focused on the crystallization of very thin high-k dielectric films around 5 nm thick, which are subsequently used as nucleation layers for the deposition of additional material at higher temperatures. The process used in U.S. Pat. No. 6,432,725 is not suitable for crystallizing magneto optic or nitride films which are an order of magnitude thicker, 50 nm or greater, to be of functional use and require higher temperatures in a plasma in order to crystallise.

There is therefore a need for an improved method of crystallising thin magneto-optic, electro-optic and nitride films at temperatures encompassing the range which is compatible with integrated circuit technology.

The reference to any prior art in this specification is not, and should not be taken as, an acknowledgement or any form of suggestion that the prior art forms part of the common general knowledge in Australia or elsewhere.

### OBJECT OF THE INVENTION

It is an object of some embodiments of the present invention to provide consumers with improvements and advantages over the above described prior art, and/or overcome and alleviate one or more of the above described disadvantages of the prior art, and/or provide a useful commercial choice.

### SUMMARY OF THE INVENTION

In one form, although not necessarily the only or broadest form, the invention resides in a method of crystallising a thin film including the steps of:
depositing a thin film on a substrate; and
exposing the thin film as deposited on the substrate and the substrate to a plasma for a time period of greater than 5 minutes, wherein:
the thin film is one of an amorphous magneto optic material, an amorphous electro optic material or a nitride material;
a gas is excited with a radio frequency (RF) field to form the plasma;
the thin film and the substrate are, in the course of being exposed to the plasma, heated to temperatures of between 400° C. and 550° C. by the plasma; and
the thin film is at least partially crystallised by the plasma.

Preferably, a longitudinal axis of the thin film is positioned perpendicularly to a longitudinal axis of electrodes that generate the RF field.

Preferably, the method further includes the step of reducing a pressure the thin film and the substrate are exposed to.

Preferably, the pressure is between 1 Torr and 6 Torr.

Preferably, the time period is between 5 minutes and 15 minutes.

Preferably, a thickness of the thin film is between 50 nm and 1000 nm.

Preferably, when the thin film is an amorphous magneto optic material, the amorphous magneto optic material is at least partially crystallised by the plasma to form an active magneto optic film.

Preferably, when the thin film is an amorphous electro optic material, the amorphous electro optic material is at least partially crystallised by the plasma to form an active electro optic film.

Preferably, when the thin film is a nitride material, the nitride material is at least partially crystallised by the plasma to form a crystallised nitride film.

Preferably a metal film is positioned adjacent to and in contact with an opposite surface of the substrate to the thin film.

Preferably, the metal film is a gold leaf.

Preferably, the metal film is a platinum leaf.

Preferably, a frequency of the radio frequency field is between 1 MHz and 300 MHz.

Preferably, the frequency is 13.56 MHz. Preferably a power of the radio frequency field is between 100 Watts and 1000 watts.

Preferably, the thin film is deposited with a low thermal budget on the substrate including one of RF Sputtering, Pulsed Laser Deposition (PLD), Magnetron Sputtering, sol gel and Ion Beam Deposition.

Preferably, the amorphous magneto optic material is a rare-earth substituted Bismuth Dysprosium Iron Gallium Garnet

Preferably, the amorphous magneto optic material is a fully substituted Bismuth Iron Gallium Garnet or an Iron Garnet rich in Bismuth.

Preferably, the amorphous magneto optic material is a rare earth substituted Bismuth Iron Gallium Garnet.

Preferably, the amorphous magneto optic material is a rare earth substituted Bismuth Iron Aluminium Garnet.

Preferably, the amorphous magneto optic material is a fully substituted Bismuth Iron Garnet.

Preferably, the amorphous magneto optic material is a Calcium doped Bismuth Iron Garnet (Ca:Bi₃Fe₅O₁₂).

Preferably, the amorphous electro optic material is Bismuth Iron Oxide (BiFeO₃).

Preferably, the nitride material is Silicon Nitride.

Preferably, the nitride material is Gallium Nitride.

Preferably, the nitride material is Iron Nitride (Fe₄N).

Preferably, the substrate is fused quartz.

Preferably, the substrate is silicon.

Preferably, the substrate is silicon carbide.

Preferably, the substrate is sapphire.

Preferably, the substrate is magnesium oxide.

Preferably, a dielectric mirror layer is deposited on the substrate between the substrate and the amorphous magneto optic material.

Optionally, the thin film is dispersed between dielectric layers to form an optically tuned cavity.

Preferably, the gas includes one or more of oxygen, nitrogen and hydrogen or a combination thereof.

Preferably, the sample is positioned away from a plasma sheath that forms near electrodes that generate the RF Field.

### BRIEF DESCRIPTION OF THE DRAWINGS

An embodiment of the invention will be described with reference to the accompany drawings in which:

FIG. 1 is a block diagram illustrating a system for crystallising thin films according to an embodiment of the present invention;

FIG. 2 is a flow diagram illustrating a method of crystallising thin films according to an embodiment of the present invention;

FIG. 3 shows a graph of X-Ray Diffraction data of an amorphous Bismuth Dysprosium Iron Gallium Garnet film on fused quartz prior to exposure to a plasma according to an embodiment of the present invention;

FIG. 4 shows a graph of X-Ray diffraction data of the Bismuth Dysprosium Iron Gallium Garnet film of FIG. 3 after exposure to the plasma according to an embodiment of the present invention;

FIG. 5 shows a graph of Faraday rotation measurements of the Bismuth Dysprosium Iron Gallium Garnet film of FIG. 3 after exposure to the plasma according to an embodiment of the present invention;

FIG. 6 shows a graph of X-Ray Diffraction measurements of a silicon nitride film on 111 silicon prior to exposure of a plasma according to an embodiment of the present invention;

FIG. 7 shows a graph of X-Ray Diffraction measurements of the silicon nitride film of FIG. 6 after exposure to the plasma according to an embodiment of the present invention;

FIG. 8 shows a graph of Faraday rotation measurements of a Bi₂DyFe₄GaO₁₂ film after exposure to a plasma according to a further embodiment of the present invention;

FIG. 9 shows a graph of temperature of a sample, without a metal film; and

FIG. 10 shows a graph of temperature of the sample of FIG. 9 with a metal film made of Gold (Au).

### DETAILED DESCRIPTION OF THE PREFERRED EMBODIMENT

Elements of the invention are illustrated in concise outline form in the drawings, showing only those specific details that are necessary to understanding the embodiments of the present invention, but so as not to clutter the disclosure with excessive detail that will be obvious to those of ordinary skill in the art in light of the present description.

In this patent specification, adjectives such as first and second, left and right, front and back, top and bottom, etc., are used solely to define one element from another element without necessarily requiring a specific relative position or sequence that is described by the adjectives. Words such as “comprises” or “includes” are not used to define an exclusive set of elements or method steps. Rather, such words merely define a minimum set of elements or method steps included in a particular embodiment of the present invention. It will be appreciated that the invention may be implemented in a variety of ways, and that this description is given by way of example only.

The inventors believe that the present invention utilizes O⁺ or N⁺ gaseous ions formed in a plasma to interact with a thin film deposited on a substrate. The gaseous ions formed in the plasma interact with the thin film and the substrate to heat the thin film and the substrate to temperatures of between 400° C. and 550° C. and crystallise the thin film to produce an active magneto optic film, an active electro optic film or a crystallised nitride film. An advantage of the present invention is that the thin film of suitable composition may be deposited on a same substrate as an integrated circuit without damaging the integrated circuit during film crystallisation.

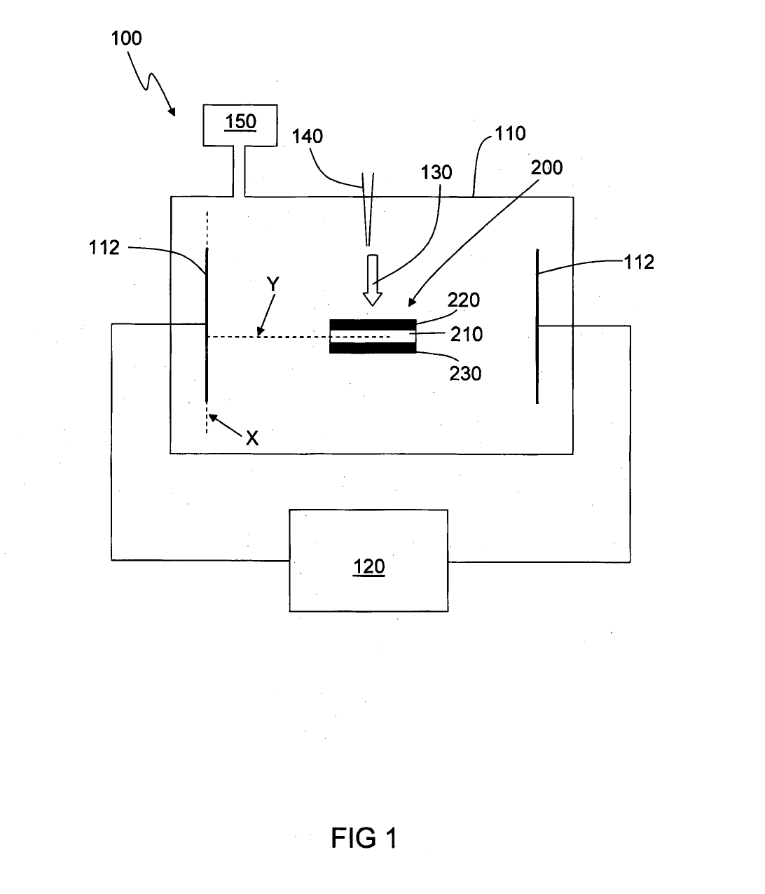

FIG. 1 shows a system 100 for crystallising thin films according to an embodiment of the present invention. The system 100 includes a plasma chamber 110, a Radio Frequency generator 120 and a vacuum pump 150 in fluid communication with the plasma chamber 110. In one design, the plasma chamber 110 includes metal electrodes 112 connected to the Radio Frequency Generator 120 to generate a Radio Frequency (RF) field inside the plasma chamber 110. The plasma chamber 110 is evacuated by the vacuum pump 150 and reduces a pressure in the plasma chamber 110. It should be appreciated however that any suitable design or type of plasma chamber 110 may be used.

The plasma chamber 110 is evacuated to a desired pressure and a gas 130 is input to the chamber 110 via a tube 140. A flow rate of the gas 130 and a rate of the vacuum pump 150 are adjusted to achieve the desired chamber pressure. The gas 130 is excited by the radio frequency (RF) field to form a plasma.

A sample 200 is positioned inside the chamber 110 for exposing to the plasma. In one embodiment, a longitudinal axis (X) of the sample 200 is positioned perpendicularly to a longitudinal axis (Y) of the electrodes 112, and away from a sheath formed in the plasma near the electrodes in order to prevent the sample from being etched. Preferably the sample 200 is positioned in between the electrodes 112. As is known in the art, the sheath is an area of the plasma which has a greater density of positive ions, thus instead of annealing or crystallising the sample 200, the sample 200 will more likely be etched. The sample 200 includes a substrate 210 to which a thin film 220 is deposited. Optionally a metallic film 230 such as a gold or platinum leaf is positioned adjacent to and in contact with an opposite side of the substrate 210 to the thin film 220. The gold or platinum leaf has a high conductivity and the inventors believe that it prevents a charge from accumulating on the substrate 210 and film 220 which opposes the ions of the plasma. Gold and platinum have the further advantage of not oxidizing when oxygen is used as the plasma gas. Measurements show that substantially higher temperatures are reached when a good conductor is placed behind the substrate.

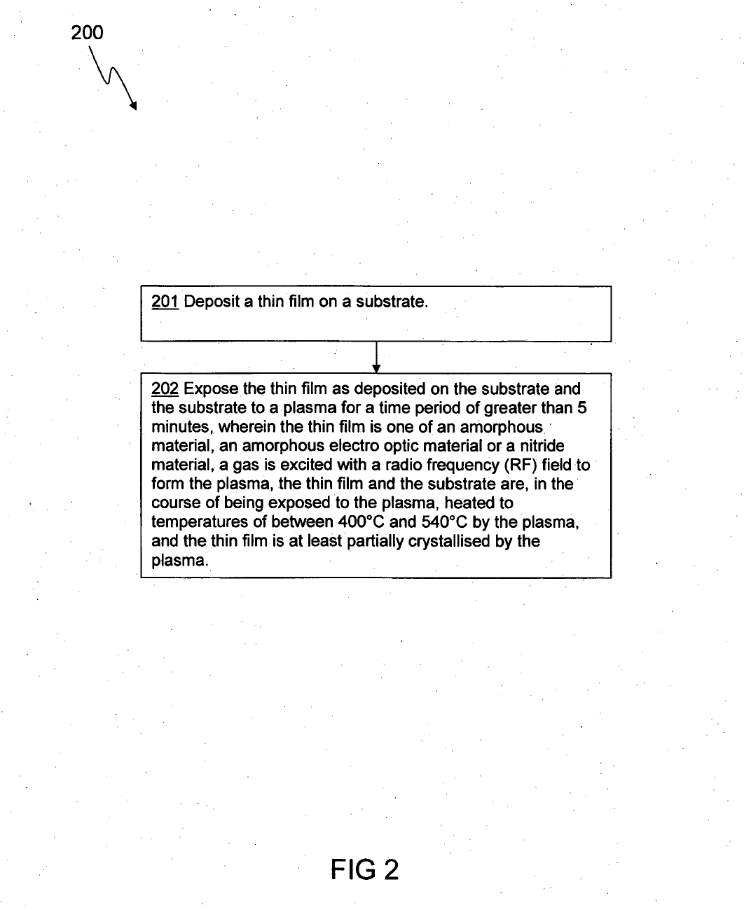

FIG. 2 shows a flow diagram 200 of a method of crystallising a thin film according to an embodiment of the present invention. At step 201, a thin film 220 is deposited on a substrate 210, with a low thermal budget. Preferably the thermal budget is below 540° C., and more preferably below 450° C. to be compatible with silicon integrated circuit technology.

At step 202, the thin film as deposited on the substrate, and the substrate and the thin film are exposed to a plasma for a time period of greater than 5 minutes. The thin film is one of an amorphous magneto optic material, an amorphous electro optic material or a nitride material. A gas is excited with a radio frequency (RF) field to form the plasma. The thin film and the substrate are, in the course of being exposed to the plasma, heated to temperatures of between 400° C. and 540° C. by the plasma, and the thin film at least partially crystallises. The temperature depends on the pressure of the plasma chamber 110, the power of the RF field used to excite the gas 130, the frequency of the RF field, an exposure time within the plasma and whether a conductor is placed next to the substrate.

For thin films 220 made from an amorphous magneto optic material such as rare earth doped bismuth based iron garnets, preferably the gas 130 is either oxygen, nitrogen or a forming gas. A forming gas is a mixture of nitrogen and hydrogen and typically contains 5% hydrogen. However a person skilled in the art would appreciate that other gases and combinations of gases may be used, such as oxygen rich plasmas which allow higher temperatures to be reached.

For thin films 220 made from a nitride material, the gas used to form the plasma is preferably either nitrogen or the forming gas as nitride films tend to develop an oxide material when using oxygen.

In one embodiment, the frequency of the RF field is 13.56 MHz with a power of 760 Watts. 13.56 MHz is chosen as it is in the Industrial Scientific and Medical band of the electromagnetic spectrum. However it should be appreciated that other frequencies and powers may be used. The frequency may be in the range of 1 MHz to 300 MHz and the power may be in the range of 100 Watts to 1000 Watts. Furthermore, the pressure inside the plasma chamber 110 may be in the range 1 Torr to 6 Torr.

A degree of crystallinity of the thin film 220 after treatment with the plasma is determined by X-Ray Diffraction (XRD) measurements. For magneto optic films the degree of crystallinity is also inferred by measuring either magnetization curves or Faraday rotation, or both.

The inventors have found that a gas 130 with an ionization energy in the range of for example 1300 Kj/mol and 1500 Kj/mol and a relatively high ion mass for example between 28 and 32 for nitrogen and oxygen respectively are required to form the plasma. In some embodiments the gas 130 is either oxygen or nitrogen. However, as previously discussed oxygen plasmas using nitride films tend to develop an oxy-nitride material and hence should not be used. In addition, a mass of the plasma ions needs to be sufficiently high (for example between 28 to 32 molecular weight) to impart sufficient energy to the film, thus gases such as hydrogen and helium do not form a sufficiently hot plasma to be suitable to achieve crystallization when used solely as the plasma gas.

An example of conditions used to achieve crystallization of rare earth doped bismuth based iron garnets and gallium nitride using plasma ions will now be described in detail below.

In the examples provided for thin films 220 below, although specific atomic ratios have been provided, it should also be appreciated that the atomic ratios can have variations from the integer values shown by example below.

In one embodiment the thin film 220 is an amorphous film of Bismuth Dysprosium Iron Gallium Garnet (for example Bi₂DyFe₄GaO₁₂) and is deposited to a thickness of 300 nm on a substrate 210 of fused quartz. However it should be appreciated that thin films 220 of other thicknesses may be used and typically in the range of 50 nm to 1000 nm.

Optionally, a dielectric mirror layer is deposited on the substrate 210 between the substrate 210 and the thin film 220. The dielectric mirror layer is used to enhance a Kerr effect by concentrating an optical field within the active magneto optic material.

In addition, it should be appreciated that the thin film 220 may be dispersed between dielectric layers (not shown) to form, or form part of, an optically tuned cavity. For example, the structure 200 may include alternating layers of the thin film 220 and the dielectric layer (not shown) disposed on the substrate 210.

Examples of other amorphous magneto optic materials that may be deposited to forth the thin film 220 are a rare earth substituted Bismuth Iron Gallium Garnet, a rare earth substituted Bismuth Iron Aluminium Garnet, and a Calcium doped Bismuth Iron Garnet (for example Ca:Bi₃Fe₅O₁₂); fully substituted Bismuth Iron garnet (for example Bi₃Fe₅O₁₂). In addition, it should be appreciated that the present invention may be used to crystallise amorphous electro optic materials, such as a fully substituted Bismuth Iron Oxide (BiFeO₃), to form an active electro optic material. Furthermore examples of other substrates 210 that may be used include silicon, sapphire, silicon carbide and magnesium oxide.

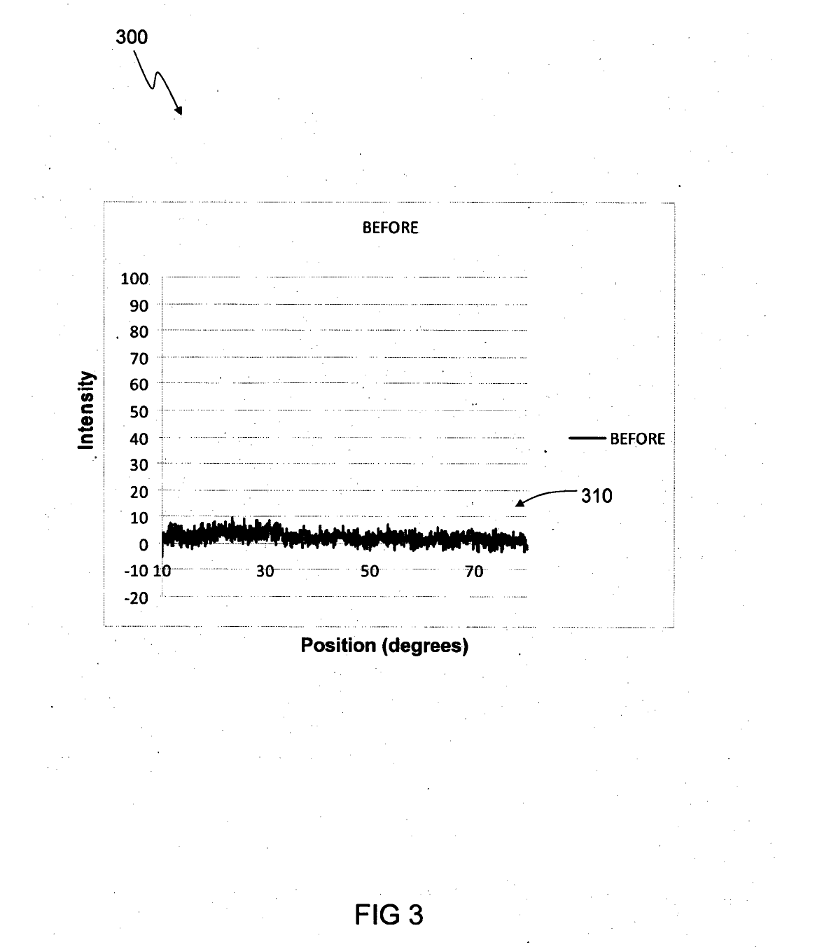

FIG. 3 shows a graph 300 of X-Ray Diffraction (XRD) data of an amorphous Bismuth Dysprosium Iron Gallium Garnet film prior to exposure to a plasma according to an embodiment of the present invention. As shown in FIG. 3, the absence of peaks in trace 310 signifies that there is no sign of crystallization.

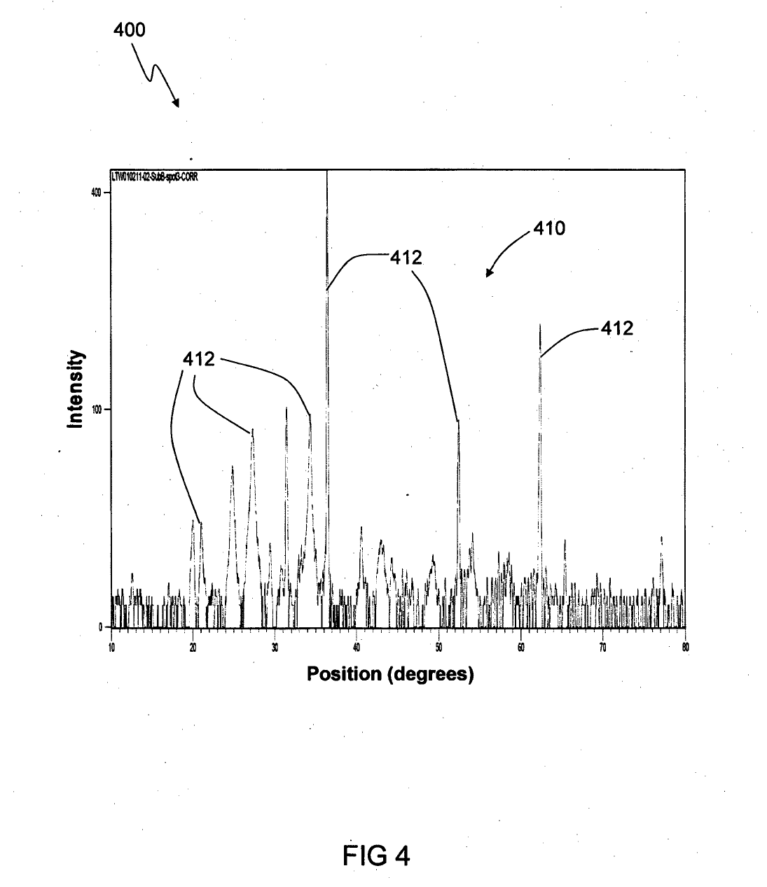

FIG. 4 shows a graph 400 of X-Ray diffraction data of the Bismuth Dysprosium Iron Gallium Garnet film of FIG. 3 after exposure to the plasma according to an embodiment of the present invention. In one embodiment, the Bi₂DyFe₄GaO₁₂ was placed in a plasma formed from oxygen. The Bi₂DyFe₄GaO₁₂ of FIG. 4 was exposed for 15 minutes, at a pressure of 3.2 Torr and using an RF power of 760 Watts at a frequency of 13.56 MHz and a gold foil was placed behind the sample next to the substrate. As shown in FIG. 4, a trace 410 of the XRD data shows typical garnet phase diffraction peaks 412 which are consistent with crystallisation.

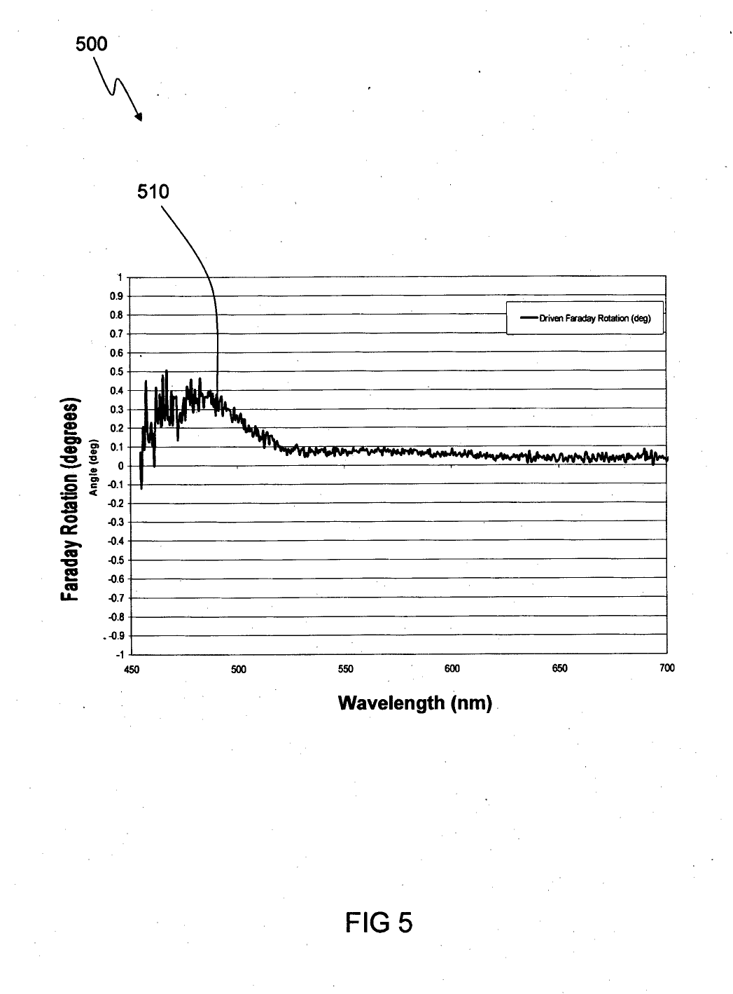

Another indication of the degree of crystallinity, and hence the production of an active magneto optic film, may be ascertained by measuring a Faraday rotation through the film 220 after the sample 200 has been exposed to the plasma. FIG. 5 shows a graph 500 of Faraday rotation measurements of the Bismuth Dysprosium Iron Gallium Garnet film of FIG. 3 after exposure to the plasma according to an embodiment of the present invention. As shown in FIG. 5, trace 510 shows some Faraday rotation which is indicative of crystallization of the Bi₂DyFe₄GaO₁₂ film. In order to achieve this level of crystallisation, the maximum temperature of the sample 200 during the plasma treatment was 520° C. In addition, transmission measurements of the plasma treated sample 200 do not indicate any optical damage caused by the plasma.

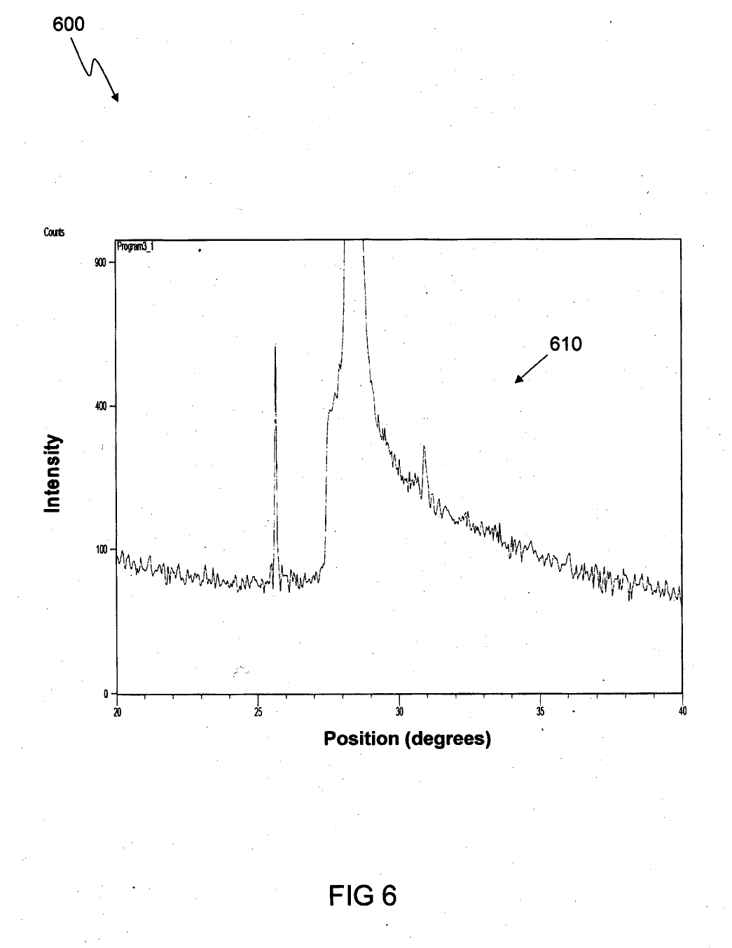

In a second example, a thin film 220 of silicon nitride is deposited to a thickness of 500 nm on a substrate 210 of 111 silicon and treated in a nitrogen plasma at a pressure of 5 Torr and an RF power of 760 Watts at 13.56 MHz for 10 minutes. FIG. 6 shows a graph 600 of X-Ray Diffraction measurements of a silicon nitride film prior to exposure of a plasma according to an embodiment of the present invention. As shown in FIG. 6, trace 610 of XRD data shows that there is some initial minor crystallization in the silicon nitride film as indicated by the small peak at 31 degrees.

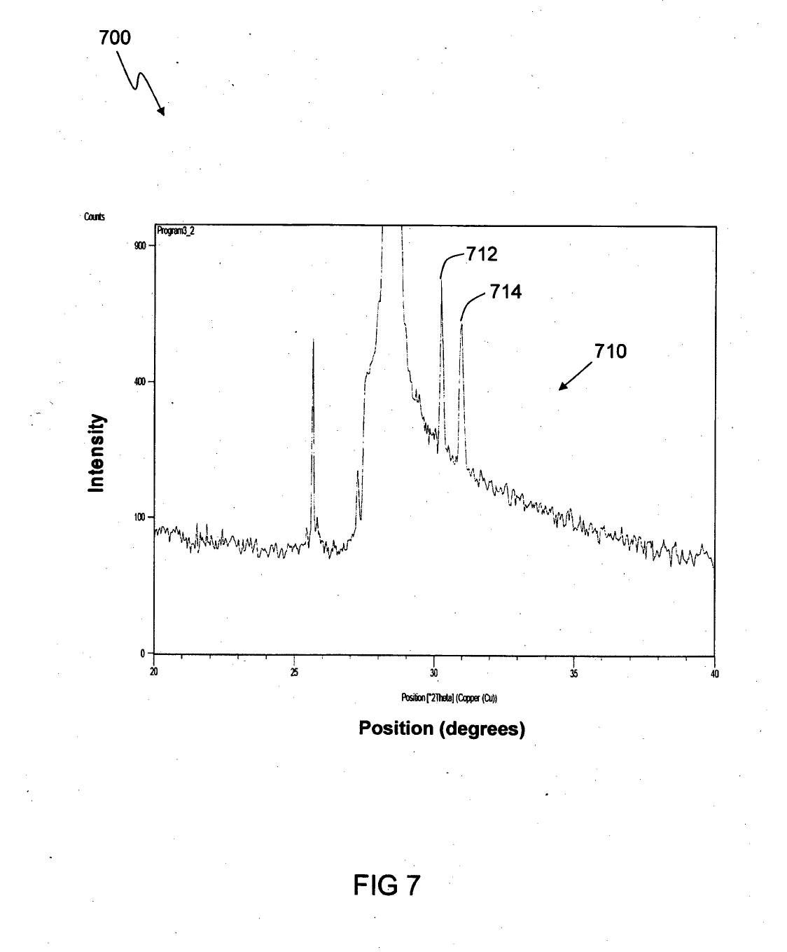

FIG. 7 shows a graph 700 of X-Ray Diffraction measurements of the silicon nitride film of FIG. 6 after exposure to the plasma according to an embodiment of the present invention. As shown in FIG. 7, trace 710 of XRD data shows an increase in crystallization of the film where peaks 712, 714 at approximately 30 and 31 degrees indicate the formation of αSi₃N₄ 201 phase and αSi₃N₄ 002 phase respectively. In order to achieve this level of crystallisation, the maximum temperature of the sample during the plasma treatment was 470° C.

It should be appreciated that other nitrides may also be deposited to form thin film 220 for example Gallium Nitride, and Iron Nitride. Similarly, examples of other substrates 210 that may be used include silicon, sapphire and silicon carbide.

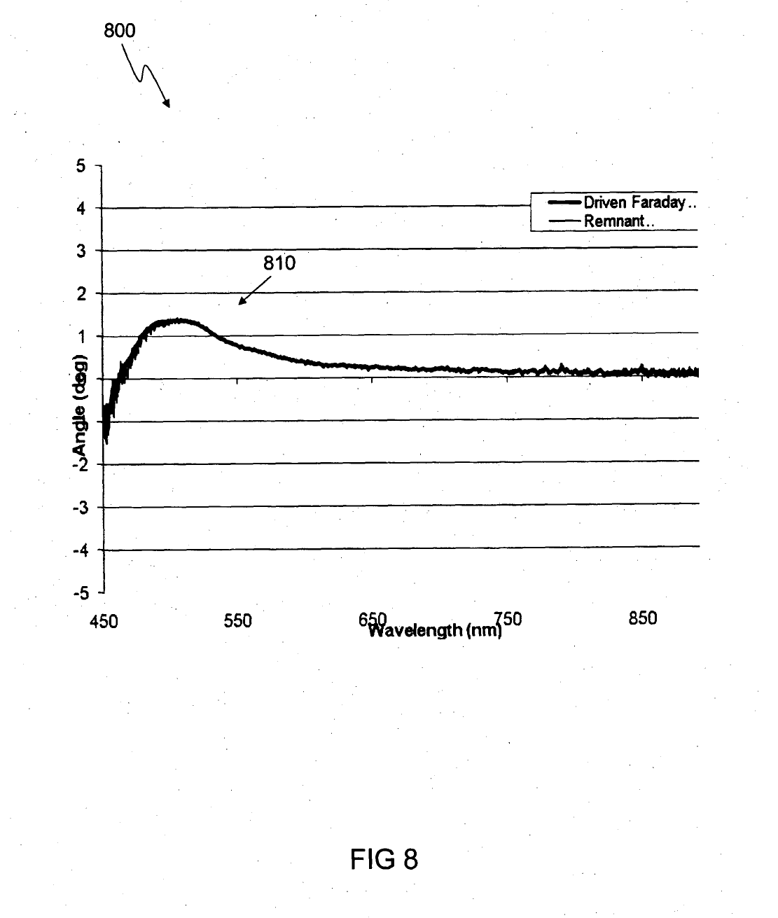

FIG. 8 shows a further graph 800 of Faraday rotation measurements of a Bi₂DyFe₄GaO₁₂ film after exposure to a plasma according to a further embodiment of the present invention. In this embodiment, the sample 200 was placed in an oxygen plasma at a pressure of 4 T, an RF power of 800 W, and an RF frequency of 13.56 MHz for 15 minutes. The sample 200 included a gold metal film 230, and the sample 200 reached a temperature 540° C.

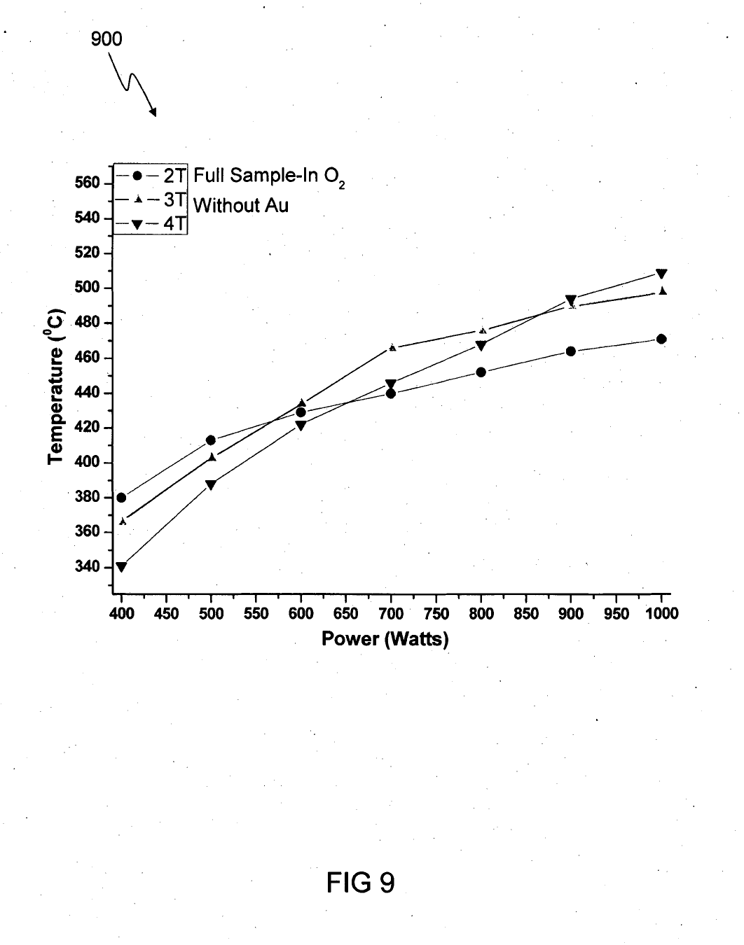

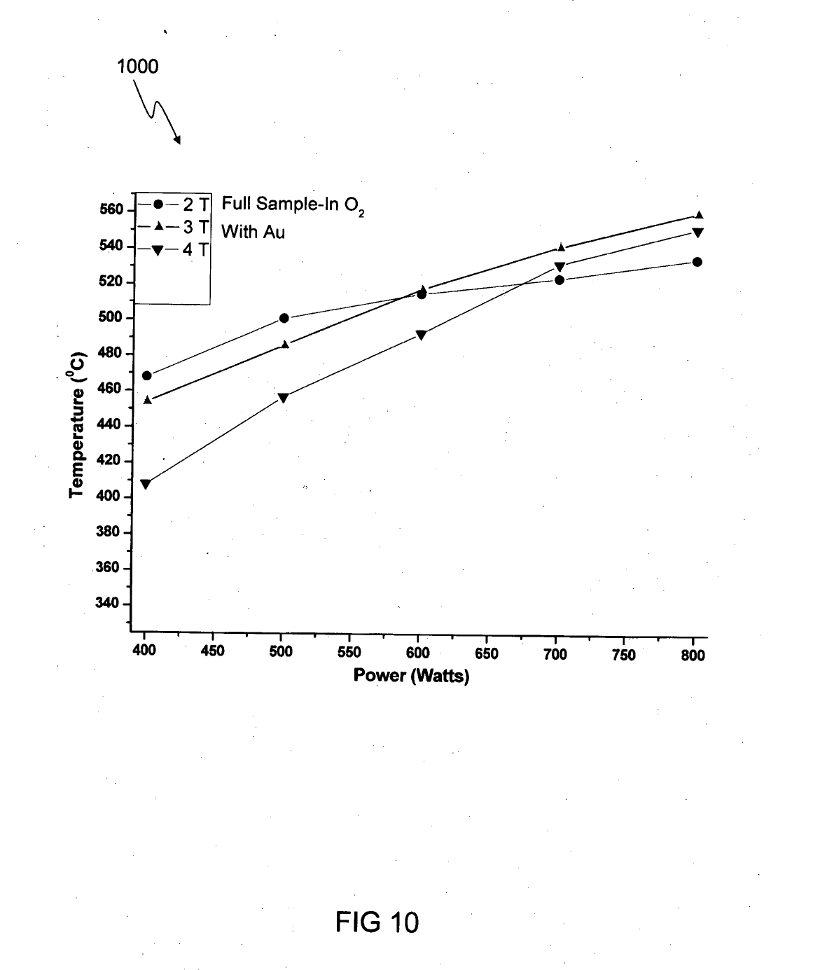

As previously mentioned, substantially higher temperatures of the sample 200 are achieved when a metallic film 230 is deposited on an opposite side of the substrate 210 to the thin film 220. FIG. 9 shows a graph 900 of temperature of a sample 200, without a metal film 220. FIG. 10 shows a graph 1000 of temperature of the sample 200 with a metal film 220 made of Gold (Au).

As shown in FIG. 10, the temperature of the sample 200 is substantially higher with a metal film 230 than a sample without a metal film 230 under the same conditions, as shown in FIG. 9. In each case, the plasma was formed from an Oxygen gas for different RF power levels (400 W, 500 W, 600 W, 700 W, and 800 W), and different chamber pressures (2 T, 3 T and 4 T). For a plasma formed from a Nitrogen gas, the temperature of the sample achieved is lower than with a plasma formed from an Oxygen gas.

An advantage of the present invention is that active magneto optic, active electro optic and crystallised nitride films may be produced on a same substrate as integrated circuits. This is because the temperature of the thin films 220 used to form the active magneto optic film, the active electro optic film or the crystallised nitride film can be kept to below 540° C., and more preferably below 470° C., which does not damage the integrated circuit.

The above description of various embodiments of the present invention is provided for purposes of description to one of ordinary skill in the related art. It is not intended to be exhaustive or to limit the invention to a single disclosed embodiment. As mentioned above, numerous alternatives and variations to the present invention will be apparent to those skilled in the art of the above teaching. Accordingly, while some alternative embodiments have been discussed specifically, other embodiments will be apparent or relatively easily developed by those of ordinary skill in the art. Accordingly, this patent specification is intended to embrace all alternatives, modifications and variations of the present invention that have been discussed herein, and other embodiments that fall within the spirit and scope of the above described invention.

1. A method of crystallising a thin film including the steps of:
depositing a thin film on a substrate; and
exposing the thin film as deposited on the substrate and the substrate to a plasma for a time period of greater than 5 minutes, wherein:
the thin film is one of an amorphous magneto optic material, an amorphous electro optic material or a nitride material;
a gas is excited with a radio frequency (RF) field to form the plasma;
the thin film and the substrate are, in the course of being exposed to the plasma, heated to temperatures of between 400° C. and 550° C. by the plasma; and
the thin film is at least partially crystallised by the plasma.

2. The method of claim 1 wherein a longitudinal axis of the thin film is positioned perpendicularly to a longitudinal axis of electrodes that generate the RF field.

3. The method of claim 1 wherein the method further includes the step of reducing a pressure the thin film and the substrate are exposed to.

4. The method of claim 3 wherein the pressure is between 1 Torr and 6 Torr.

5. The method of claim 1 wherein the time period is between 5 minutes and 30 minutes.

6. The method of claim 1 wherein a thickness of the thin film is between 50 nm and 1000 nm.

7. The method of claim 1 wherein, when the thin film is an amorphous magneto optic material, the amorphous magneto optic material is at least partially crystallised by the plasma to form an active magneto optic film.

8. The method of claim 1 wherein, when the thin film is a nitride material, the nitride material is at least partially crystallised by the plasma to form a crystallised nitride film.

9. The method of claim 1 wherein, when the thin film is an amorphous electro optic material, the amorphous electro optic material is at least partially crystallised by the plasma to form an active electro optic film.

10. The method of claim 1 wherein a metal film is positioned adjacent to and in contact with an opposite surface of the substrate to the thin film.

11. The method of claim 10 wherein the metal film is one of a gold leaf and a platinum leaf.

12. (canceled)

13. The method of claim 1 wherein a frequency of the radio frequency field is between 1 MHz and 300 MHz.

14. The method of claim 1 wherein the frequency is 13.56 MHz.

15. The method of claim 1 wherein a power of the radio frequency field is between 100 Watts and 1000 watts.

16. The method of claim 1 wherein the thin film is deposited with a low thermal budget on the substrate including one of RF Sputtering, Pulsed Laser Deposition (PLD), Magnetron Sputtering, sol gel and Ion Beam Deposition.

17. The method of claim 1 wherein the amorphous magneto optic material is one of a rare earth substituted Bismuth Dysprosium Iron Gallium Garnet, a fully substituted Bismuth Iron Gallium Garnet, an Iron Garnet rich in Bismuth, or a Calcium doped Bismuth Iron Garnet.

18. The method of claim 1 wherein the amorphous electro optic material is fully substituted Bismuth Iron Oxide (BiFeO₃).

19. The method of claim 1 wherein the nitride material is one of Silicon Nitride, Gallium Nitride or Iron Nitride (Fe₄N).

20. The method of claim 1 wherein the substrate is one of fused quartz, silicon, silicon carbide, sapphire or magnesium oxide.

21. The method of claim 1 wherein a dielectric mirror layer is deposited on the substrate between the substrate and the amorphous magneto optic material.

22-23. (canceled)
